(19) United States
(12) Patent Application Publication
(10) Pub. No.: US 2009/0179780 A1
(43) Pub. Date: Jul. 16, 2009

(54) HAND-HELD THUMB TOUCH TYPABLE ASCII/UNICODE KEYPAD FOR A REMOTE, MOBILE TELEPHONE OR A PDA

(76) Inventor: Mohan Tambe, Maharashtra (IN)

Correspondence Address: GREENBLUM & BERNSTEIN, P.L.C., 1950 ROLAND CLARKE PLACE, RESTON, VA, 20191, US

(21) Appl. No.: 12/066,213

(22) PCT Filed: Sep. 7, 2006
(86) PCT No.: PCT/IN06/00343

§ 371 Date: Mar. 7, 2008

(30) Foreign Application Priority Data
Sep. 9, 2005 (IN) 1093-MUM2005

(51) Int. Cl. H03M 11/04

(52) U.S. Cl. 341/23

(57) ABSTRACT

A hand held thumb touch typable ASCII/UNICODE keyboard that has an alphanumeric keypad having multiple quad keys and multiple dual keys, and a navigation keypad having multiple dual keys and single-function keys. Each corner of one of the quad keys or dual keys of the alphanumeric keypad allow a user to type a separate character. In addition, a homing key is located at the center of the alphanumeric keypad. An optional pointing device and an adjustable hand-strap can also be added to the device.

### TECHNICAL FIELD

This invention relates to the field of ASCII/UNICODE touch-typing keyboard for electronics devices.

### DESCRIPTION OF THE BACKGROUND ART

The advent of conventional typewriters and their keyboards enabled a user to use fingers of both the hands to type accurately and faster. The technique of “Touch-typing” was gradually developed whereby it was possible to type with both hands, without looking at the keyboard. Touch-typing, permitted an author to remain in his thought plane while the fingers automatically transcribed the thoughts on the paper. With the advent of the “soft touch” computer keyboards—way was ultimately paved for knowledgeable users to compose and send e-mails.

However, the typewriter keyboard, especially with its infamous “QWERTY” layout, has generated its share of problems too—limiting the application areas. It is meant to be operated by both hands, and further more with a proper seating posture. Generally people with less typing skills, get reduced to hunt & peck typing with one or two fingers. Once people get used to the “sight typing” habit, it comes in the way of learning touch typing, which requires systematic use of fingers. In sight typing a person gets impaired in speed, and cannot manage automatic typing action required for on-line authoring.

Even a person knowing touch-typing faces problems. The QWERTY keyboard in PCs overloads the weaker fingers of the hands while almost ignoring the thumbs (which are much stronger with more brain support)—leading to the danger of RSI (Rapid Strain Injuries). Accuracy is now dependent on using everywhere the exact physical layout of the keys. This rules out the smaller adaptation of QWERTY keyboards in laptops and PDAs (Personal Device Assistants). The QWERTY keyboard has to be perched on a proper flat surface and requires a proper ergonomic seating posture. This precludes efficient use of portable, wireless QWERTY keyboards from, say, a sofa. Furthermore, since both the hands get tied up—it precludes, say, typing while having a snack. All this comes in the way for recording of thoughts while on the move. The good-old paper diary still remains handy.

The recent PDAs (Personal Digital Assistants) supports miniature QWERTY keyboard layouts. With this, the PDA is grasped between two hands and the two thumbs are used to type on the miniature keys. The same method is used in “Digital Diaries” and two-way Pagers, which have slightly longer QWERTY keyboards. The disadvantage lies in blocking both the hands. Furthermore, only sight typing is possible—preventing effortless transcribing of thoughts. Thus, practically these devices get relegated to those activities requiring keying of only small amount of text.

In parallel, however, another trend has been on the upsurge. It all started with usage of the TV remotes and cordless phones. The keys on these devices could be handled by one hand—either hand. Both of these devices sported a numeric keypad, allowing numbers to be typed with one hand. The most convenient method of typing was using the thumb of the hand while clasping the device in the palm. This trend was soon popularized in the mobile telephones, which were designed for a single-handed operation. The mobile devices, required simple entry methods for entering or searching for names. This was achieved by adapting the “ABC” overlay available on conventional telephone keypads. Each letter was input by multiple pressings within a short interval of time. The need then came for sending simple messages. Some mobile devices facilitated this by providing a spelling dictionary backed entry method such as “T9”. This obviated the need for multiple presses and resolved the ambiguity in word spelling by consulting a built in spelling dictionary. A number of other numeric keypad overlays have been invented, each requiring multiple presses. These are difficult to learn and are suitable only for short text entry.

For proper email facility on a mobile telephone, the manufacturers still had to resort to miniaturized QWERTY keyboard, or stylus based writing on a touch-pad. Both of these require use of both hands and are unwieldy to use while on the move.

Therefore there is a need for a small hand-held device for allowing typing of all the ASCII characters, and permitting both sight typing and touch-typing.

### SUMMARY

The invention thus proposes to fill the vacuum for a full ASCII keyboarding device, which can become part of mobile phones, PDAs, two-way pagers, remotes and other hand-held computing/communication devices. It extends the habit of handling the numeric keypad of mobile devices, to full ASCII keyboarding along with navigation keys—all this with the thumb of a hand. It allows convenient hunt & peck typing for immediate use by anyone. It facilitates quick learning (from kids to grand-parents) by providing a straightforward “ABCD” layout.

The keyboard layout of the device is not just “user friendly”, but “user obvious”. By making the device look familiar, the initial resistance for usage disappears. A new user can start tinkering with the device without any guidance. The features of the device become clear through the usage itself. Alternatively, it becomes easy for people to casually introduce the device to each other. Features, once explained should be hard to forget.

The keyboard layout permits “thumb touch-typing” without having to look down on the key labels. Care has been taken to allow convenient, alphabetic/phonetic typing of European scripts and many other scripts of the world, which are part of the UNICODE character set. Indeed, the keyboarding device can be used for output of ASCII/UNICODE character codes, which can be displayed on the accompanying internal display (LCD) of the device, or on an external display such as a PC monitor or a TV. Thus, the device would permit remote single-handed operation, equivalent to that of a PC keyboard.

By providing the missing ingredients, the invention would permit convergence of portable devices for communication, computing and multimedia—into a single pocketable device. This would permit evolution of a single device, which combines the features of a Telephony, Internet Browser, PDA, and Remote control. This device can always remains connected to a local/global wireless network, allowing usage in myriads of applications, limited only by imagination.

This universal keyboarding device, would form the basis of an Electronics Nervous System, by which people can keep in touch with other people and devices connected to the internet, where-ever they are.

### A→OBJECTIVES OF THE INVENTION

1. To provide capability of typing all the ASCII characters through a hand-held mobile device.
2. To ensure that the device can be operated equally well by either hand. This will, make people ambi-dexterous, and allow them to use the hand which is free at the moment. The device can be swapped between hands to reduce fatigue during extended usage.
3. To provide a layout, which can be sight typed (hunt & peck), by anyone who knows the English alphabet. This should appeal equally to a child who has just learnt his alphabet, as well as an elderly person who is reluctant to tackle the QWERTY layout of the existing keyboards.
4. To provide a key layout, which is thumb typable and can accommodate large variations in hand sizes and thumb-sizes.
5. To provide a key layout with sufficient tactile and positional feedback, so that it can be touch-typed without directly looking at the keyboard. (Thumb typing has to be conducted in an eyes-off manner, in order to become thumb touch-typing).
6. To provide a layout which with normal usage would automatically transform the sight-based thumb typing habit to eyes-free thumb touch-typing habit.
7. To ensure that there is no conflict in motor-memories (kept in cerebellum) for the people who can touch type on existing QWERTY keyboards, when they learn to touch type on the hand held device.
8. To provide single-stroke typing for the basic 26 letters of the English alphabet, 10 Digits as well as the Space and the Dot key. This should be achieved, without requiring pressing of any Shift key. The Dot key is most important punctuation, required for every sentence, as well as in any Decimal number.
9. To ensure that the layout of the Digits remains the same as in the numeric keypad of a telephone instrument, while accommodating the extra keys for alphabets. No special key such as “Num Lock” should be needed for selecting between Numbers and alphabet.
10. To provide a layout which in spite of having more than 38 keys, is still perceptually as simple as a numeric keypad of a mobile telephone. The objective is to avoid any mental inertia associated with learning of a complex looking device.
11. To provide ergonomic positioning of a hand for thumb-typing, for ensuring that Repeated Strain Injury (RSI) during thumb-typing becomes improbable.
12. To provide a convenient Homing key, which would serve as a reference for stroking all other alphabet keys.
13. To adhere to a straightforward “ABCD” layout and ensuring that it remains optimal for usage.
14. To eliminate the need of the “Shift” key as used in the conventional QWERTY keyboard, for changing between lower and upper-case alphabet or in general to select a related character. This eliminates the extra thumb travel required for stroking a separate Shift key.
15. To provide a Punctuation overlay on top of the basic alphabet keys, which can be easily remembered due to grouping of similar punctuations. All the punctuations should get derived through a SHIFT key.
16. To provide a simple and intuitive method for keying the additional letters with diacritic mark in European languages. These letters are awkward for keying even on the conventional keyboards with QWERTY layout. Another objective is to provide Extended ASCII or UNICODE character codes for European language.
17. To provide a simple and intuitive method for keying the commonly used symbols, which are not found in the ASCII character set. Example: Degree, Copyright, Trademark, Euro, Yen etc. This again is a weak point of the existing QWERTY keyboards. These codes should correspond to Extended ASCII or UNICODE character set.
18. To provide a simple and intuitive method for keying all the non-Latin languages of the world using the basic English alphabets on the keyboard for reference. It should be possible to easily mix English with other languages.
19. To provide a thumb typable Navigation keypad, which will be used for direction oriented activities such as browsing, scrolling, cursor movement, TV/VCR/PC control, games etc. The Navigation keypad should also include the commonly required keys for TV control. Even on the PC keyboard, the Navigation keypads is not accessible without removing the hand from the homing position.
20. To provide an adjustable Hand strap, which would hold hand in the proper position for thumb-typing, and ensure that the homing position is facilitated.

### B→SUMMARY OF THE INVENTION

The mentioned Objectives are attained by the following design philosophy.

### Basic Design of Alphabet Keypad

### Design Constraints

A hand-held keyboarding device meant for usage by either hand has to abide by lot of restrictions. Unlike the horizontal profile of a QWERTY keyboard, it has to have a vertical profile of a TV remote or a mobile telephone—which can be handled entirely by one hand. This category normally confines itself to a 12-key numeric keypad and some dedicated function keys. A keyboarding device, however, has to be able to cater to at least the entire 96 displayable characters and some additional control characters in the ASCII code set.

The numeric keypad layout has to be retained while accommodating extra keys required for the Alphabet, Space key and the Dot key. The numbers and alphabet should be typable with one hand itself.

Many users have become expert in typing digits and even alphabetic SMS messages using the alphabet on the numeric keypad of their mobile telephone. A letter is typed by pressing a digit key several times. Multiple presses can be avoided by using the “T9” keyboard, which uses an internal spelling dictionary for the most commonly used words. The popularity of the SMS messaging on mobiles has shown the tremendous utility of a single-handed typing—which is possible even on the move.

The bottle-neck remains for typing longer messages and emails on a mobile devices. This normally necessitates a full function ASCII keyboard with Navigation keys, which can increase the size of the mobile device. The crux of the problem is typing all these keys by the same thumb in a convenient manner, without having to keep shifting the palm grasping position. In other words all the keys have to be “thumb typable”.

### Thumb Typing

Thumb is more suited for typing compared to other fingers—due to larger musculature, nerve endings and brain area for controlling it. The weaker fingers are prone to RSI (Rapid Strain Injury), in traditional typing on QWERTY keyboard. Thumb typing, would avoid RSI problems—and allow usage by almost all the people.

Thumb typing considerations would first limit the area in which the keys can be conveniently stroked by the thumb. Moreover the hand has to grasp the device in a manner that the thumb could be as much as possible in parallel with the top surface.

The invention overcomes the above problem by realizing that the “reach” of the thumb increases significantly by raising it high above the key surface, while continuing to grasp the device. This can't occur if the device rests in the palm, forcing the thumb to be close to the keys. Rather, the device needs to rest only on the fingers, with the palm curling up along the side of the device and raising the thumb high enough, to flex freely from its joint.

A hand strap is needed on the bottom surface of the device to ensure that the device doesn't slip off the fingers. The hand strap would allow holding the device in a fixed position, for allowing consistent stroking of each key by the thumb. Consistency in stroking is the major requirement for “eyes-off” or touch-typing to develop. The “motor learning” for thumb would be facilitated by ensuring that each key has unique and clearly distinguishable geographical position, shape and tactile feed-back.

### Homing Key

Touch-typing learning ease and accuracy depends on a well-designed “homing position”. The conventional QWERTY keyboard, uses the center row for “homing” the four fingers of each hand. For thumb typing, the need is to find a home key for the thumb, which allows re-synchronizing, at-least once every word. Fortunately, the “Space” key admirably fits the role. Using the Space as Homing key, does justice to the most frequently typed character.

The Homing key for a Numeric keypad is ‘5’. Thus the Space has to be co-located with the ‘5’ key.

The Homing key being the “center”, other keys in the “Alphabet keypad” have to be placed around it, such that the average travel between the Homing key and each alphabet is minimized. All this has to be achieved within the constraints of the thumb typable area. The width of this area has to be that of a normal TV remote. The height of the area can be a bit more. The height of the “Alphabet keypad” has to be minimized so that a “Navigation keypad” can be accommodated above such that it too remains thumb typable from the homing position. There is no possibility of accommodating any other keypad below the Alphabet keypad, since the thumb has limited reach in the downward direction.

The variations in hand sizes can be accommodated by ensuring that the Homing key and the surrounding Alphabet keypad, remains in the thumb-typing domain of even the smaller hands of 5 year-old children, who know their ABCD. Their thumbs may not be able to cover fully the Navigation keypad located above the Alphabet keypad—but in this case the other hand can stroke those keys.

### Extending Numeric Keypad Layout

People are already used to presence of the legends of three or four letters after a Digit in a numeric keypad of a telephone or mobile. These letters are typed in a separate mode, through multiple pressing of a key, or by predicting spellings as in case of T9 mode.

It is possible to extend a normal key into a Quad key, which is pivoted at its centre and allow four characters to be output, by pressing of its corners. Each key in the Numeric keypad can now be changed into a Quad key, with the concerned digit being output by pressing the top left hand corner. Three additional characters can now be accommodated on each key, these can then be the alphabet and the Space key.

The Space character needs to be on the Home key, which is the ‘5’ key at the Centre. The Space can be located just below the ‘5’ in the Home Quad key.

26 letters and Space can be accommodated in the 27 positions available on the top nine Quad keys of the numeric keypad. This layout is such that each of the periphery key is adjacent to the home key. This tremendously facilitates touch typing.

There is no need of converting the bottom three keys of a Numeric keypad to Quad keys, as all the alphabet have been accommodated above. More over, we need to keep the vertical profile of the Numeric keypad as compact as possible, for decreasing the span of the thumb movement. However, we still need to accommodate the “Dot” key and some important Control keys. This is possible, by using Dual keys for the bottom three keys. The legends on these Dual keys would be on the left and right side.

The ‘0’ Dual key, would have the Digit itself on the left hand side (to match with other digits), and can have the “Dot” character on its right. This would facilitate intuitive use of the Dot as a decimal point while typing numbers, and full-stop while typing a sentence.

### Control Keys

The Dual keys on the Left and Right can allow four Control keys. These need to be the most important keys needed during text entry. One key has to be the SHIFT key, which would allow typing of all the Punctuations. Another key has to be the SYM (Symbol) key, which allows typing of special characters, or extra characters of Languages other than English. This leaves us with two key positions, which need to go to BS (BackSpace) and ENTER functions, necessary for text editing. TAB character can be accommodated by outputting it on a “Long press” of the Enter key.

The requirements for typing ASCII/Extended ASCII won't be complete, unless some Control keys can also be typed. In the QWERTY keyboard, Backspace, Delete, Tab and Enter keys are the prominent Control keys, surrounding the 47 displayable keys. As the Tab key is required infrequently in modern text-entry operation, it can be placed in the Long press position of the Enter key. The Backspace key needs to be an “auto-repeat” key, eliminating the possibility of generating a different character in the Long press position. The SHIFT key, can now be used in its generic sense for allowing a different but related character to be derived from a key. Thus if the SHIFT key is pressed before the Backspace key, it functions as a DEL key (with auto-repeat). If the SHIFT key is pressed before the TAB key it will function as a Back TAB key.

This way all the important characters of a PC keyboard are accommodate in 9 Quad keys, and 3 Dual keys. These 12 keys are kept exactly according to the layout of a Numeric Keypad, with the Digits showing up on the top left hand corners.

### Extending for Other Languages

European Characters & Symbols Through SYM Key

We have accommodated ASCII character set on the Numeric/Alphabetic Keypad. ASCII, however, only caters to the English language. The extra characters required for European languages are contained in the Extended ASCII character sets. The additional European characters are generally formed by attaching a diacritic mark on an English letter (also called Latin letter). Extended ASCII also contains special “ligature” characters, and symbols such as “euro”, “trade-mark” etc. Various language-specific overlays exist on top of QWERTY keyboard for typing these characters—many of them changing position of some ASCII characters, and deriving additional characters by using a “Compose” operations. The Compose operation on a PC keyboard, involves pressing of “Alt” or/and “Control” key along with a character key. Many symbols, are actually typed in PC, by entering their three-digit code value using Alt key and the Numeric keypad. Needless, to say it is all very confusing and confounded—a legacy of patch on top of patch.

The invention aims to rationalize typing of the Extended ASCII character set, through an additional “Sym” (Symbol) key. The Sym key has to be followed by one or two keys for intuitively indicating the character to be derived. Thus “AE” ligature would be derived by pressing “A” and “E” keys following the Sym key. The letter with an Umlaut can be generated by pressing Sym key, “colon” key (has two dots, as in umlaut) followed by the letter key. The Short or Long press of the letter key would, as expected, make the change in the case of the derived character too. The Euro symbol can be derived by following the Sym key by the “e” key. However, for the sake of keeping a uniform pattern for typing two keys after the Sym key, and accommodating a larger number of easily remembered symbols, we would use the Space key between the Sym key and the “e” key. The Space key after the Sym key would indicate that a non-language specific symbol is being derived, example: Sym key, Space key and “t” would derive the “trade-mark” symbol. Use of the Space key, contributes to ease in typing the symbols.

### CapsLock Key

For obtaining the same convenience, as in the QWERTY keyboard, a Caps-lock key would also be required. During Caps-lock, the upper-case alphabet would be in the Short press positions, while the lower-case alphabet would be in the Long press positions. Naturally, when the Caps-lock is active, the Sym key would derive the appropriate upper-case European character.

Again, from the compaction, consistency and ease of remembering reasons it would be desirable to put the Caps-lock key in the Long press positions of the SHIFT key. The LED adjacent to SHIFT key can indicate the CapsLock status. It can be made to blink when the SHIFT is pressed, and a following character needs to be typed.

### Script Lock Key

The Script Lock key would allow toggling between the English overlay (Script Lock off and a Script overlay (for a script selected through some menu). As the SYM key is used for deriving extra symbols, it would be intuitive to place the Script Lock key in the Long Press position of the SYM key. The LED adjacent to SYM key can indicate the status of Script Lock. This LED can be made to blink if just the SYM is pressed, and a following character needs to be typed.

The invention does not limit itself to character set in Extended ASCII, and allows generation of codes for many languages contained in the UNICODE character set. For ease of learning and convenience of operation, phonetic Script overlays are defined for each of these languages. If the script is case sensitive these Script overlays would consist of a lower-case and a upper-case overlay. The additional characters required for the language are derived through the SYM key. In this scenario, the “Script Lock” key would allow toggling between the English overlays and the Script overlays. For a language such as Cyrillic, which has both lower and upper case alphabet—the Alpha and Caps overlay would be displaced by the equivalent in Cyrillic. For languages such as the Indian, Perso-Arabic and Chinese, which don't have case differentiation only one Script overlay would be normally chosen, irrespective of the state of the Caps lock. However, it is possible to use the Caps lock key for defining additional special purpose overlays for the script. Example: although Indian scripts require only one overlay, some of the additional characters required for Sanskrit/Vedic can be output when the Caps lock is on.

### Physical Realization

Physical Layout Using Key Blocks

The Alphanumeric keypad, (FIG. 1) thus comprised of three rows of three Quad Keys with the Home Quad Key in the centre. Each key of the Quad Key, is activated by pressing one of the corners. The fourth and the bottom row comprises of three Dual Keys, with the keys in horizontal orientation. There are total 12 keys in the Alphanumeric keypad, the same as that in a conventional Numeric keypad.

It is possible to squeeze all these keys in a thumb typable area of 4.5 cm (width) by 6.5 cm (height) by using miniature keys as used in remotes and mobile hand-sets.

The invention, takes care of these fundamental problem in the physical layout of the keys by taking into account human engineering factors such as mental imagery, procedural memories and motor learning. The key concept lies in perceptual simplicity ushering navigation and learning simplicity. The human mind can comprehend instinctively, without strain, only a few things (3 or 4 ideally) at a time. So while, at the top level the layout looks like the familiar Numeric keypad (with alphabet legends), each Quad key comprises of only four options, out of which the position of the Digit is known before hand.

The Quad Key being a perceptual device, can be implemented as a four-way rocker switch, two two-way rocker switches, or even four plain switches. Care has to be taken that the four switches, blend into a single Quad Key, with a concave surface which raises the four corners. Simultaneous pressing of two or more keys in a Quad Key can be prevented through appropriate mechanical design as well as electronics logic.

As discussed earlier the thumb is kept as parallel as possible to the keys, so that the key corner can be felt accurately. The motor learning technique involves moving from the homing position to one of the adjacent Quad Keys, and then stroking one of its corners. This two-step divide and conquer process, considerably simplifies the task of pressing any of the 36 alphanumeric keys.

Since a Quad Key becomes considerably more compact than equivalent four separate keys, it is possible to give extra space between the Quad Keys to make navigation easier, without possibility of adjacent Key blocks getting pressed.

The bottom row has three Dual keys. For perceptual simplicity and ease in use, these are recessed below the Quad Keys. The recessed position allows the Dual keys to be placed quite close to the Quad Key blocks, optimizing the height of the Alphanumeric keypad.

### Assigning Legends to Keys

The simple and familiar “abcd” layout is used for assigning legends to the Alpha overlay. The QWERTY layout is not amenable for vertical layout and thumb-typing. More-over QWERTY layout is intimidating to the non-initiated people. The kids and uninitiated people, love using the intuitive “abcd” layout. The “abcd” layout though, has been further optimized for ease of use and learning: this is in contrast to the non-uniform distribution of alphabet on a telephone keypad. The layout design in fact reveals the neat structure of the English alphabet. The top-left position of a Quad Key is occupied by a Digit conforming to that of a telephone keypad. The remaining three keys of a Quad Key contains three consecutive letters—leading not only to perceptual ease, but intuitive intra key-block navigation for consecutive character typing. Continuing in this manner, the Home Quad key, has the Space character below the Digit, and the two central letters “m” and “n” of the alphabet. So while the first Quad Key started with “abc”, the last Quad Key ends up with “xyz”.

Phonetically speaking, the six vowels “a”, “e”, “i”, “o”, “u” & “y” are on separate Quad keys. Each word of the English language has to contain one or more of these vowels—the direction of initial navigation for these are then distinct. The two Nasal consonants “m” and “n” are on the Home Quad Key.

The central Dual key has the ‘0’ digit on the left hand side, and Dot on the right hand side. Dot is required in every sentence and for typing decimal numbers.

The conventional numeric keypad has got “*” and “#” keys on the left and right side of the “0” keys. It is not prudent to assign separate keys for them, since they are not used often compared to other functions such as SHIFT, Backspace, ENTER etc. Thus the “*” and “#” keys are accommodated on the Shift positions of the Quad Keys on the left and right of the Home Quad Key.

### Placing SHIFT and SYM Keys

The SHIFT key is just below the “,” key, which is a prominent punctuation next to the dot. Other important punctuations such as dash, single and double quotes, colon, and semicolon, are placed in the bottom row, above the SHIFT key, to make their usage easy.

The SYM key gets used along with diacritic mark keys such as “̂”, “`”, “′”, “:”, “~” and “v” for deriving appropriate combination with a vowel or a consonant. This, process, become straight forward for usage and learning, since these keys are located in the bottom row, just above the SYM key and in the path of traversal towards the subsequent character—optimizing the total traversal required for deriving the new character.

### Calculator Keypad

The Alphanumeric keypad has been optimized as a Calculator keypad too, where apart from Digits and Dot, all the Operation keys can also be used directly. In this mode the alphabet keys are not used, which allows direct typing of some of the Operation keys such as “*”, “−”, “+”, “%”, “/”, “=”, without using SHIFT key. In fact the Calculator can be used as Hex Calculator too, since “a”, “b”, “c”, “d”, “e”, and “f” can also be used. If necessary the brackets “[” and “]” can also be used.

Scientific Calculator functions can also be invoked by typing SHIFT “c” for “cos” etc.

### Features for Completeness

Navigation Keypad

In order to be self-sufficient, like a PC keyboard, the device needs to have a Navigation keypad too. This would allow functions such as moving a cursor, scrolling, browsing and menus. All this should be thumb typable, so that one can keep looking at the TV/PC screen while moving a cursor. It should also provide volume, mute control, and on/off button needed for TV and Audio devices.

The Navigation keypad is located above the Alphanumeric keypad, since a thumb has flexibility of reaching for more keys in the upward direction. To cater to various sizes of hands one has to minimize the number of rows in the Navigation keypad to the minimum. Four direction arrows with a central “selection” key, would require minimum of three rows. There can be four additional keys in the diagonal direction from the “selection” key. These can cater to selection of modes, menus, and provide some browsing keys.

The top row provides Mute, Volume Up/Down and TV On/Off keys.

A child's hand may not fully cover the Navigation keypad. In this case the fingers of the other hand can be used. In fact, for simple browsing applications such as for TV/VCR and presentations, the Navigation keypad can be operated without inserting the hand in the Hand strap.

### Learning the Keyboard

The Alphabetic overlay is designed to immediately appeal to a first time user, whether he is familiar or not with the QWERTY keyboard. Since the horizontal layout of QWERTY keyboard and the vertical profile of the “abcd” keyboard is quite different, there will not be any visual-memory conflict in usage. Since the finger motor memories used in QWERTY touch-typing are very different from thumb motor memories needed for thumb touch-typing—there won't be any conflict in touch-typing.

The Alphabetic overlay, would allow the sight typing practice to automatically yield skills in touch typing—without any special training (as required for QWERTY keyboards). This is possible, because the stroking of all the keys are done in a consistent manner by the thumb, facilitating the motor-memory (stored in the cerebellum).

A beginner should hold the device properly, by inserting the fingers of a hand in the Hand strap, and ensuring that the thumb is in proper position for stroking the keys. The palm of the hand should curl around the side of the device such that the thumb is high enough for stroking easily the extreme keys. The angle of the hand with respect to the device can be adjusted such that the thumb remains, as much as possible, parallel to the keys. The keys should be preferably stroked by the flesh of the thumb below centre of the nail. The homing position should be the most convenient position, instinctively sensed by the thumb. Once comfortable, the grasping position for the device should not be changed in subsequent usage.

A user can initially, always return back to the homing position after stroking a key. This will establish the initial mental-map required for accurately and instinctively stroking all the characters. The user should first practice touch typing of the numeric keys, as required for dialing telephone numbers. After this the user can type in all the letters belonging to the same Quad Key, before returning back to the homing position. Subsequently, characters in adjacent Quad Keys can be stroked before returning back to the homing position. Finally, the words can be typed directly, with the homing being achieved automatically while typing the Space character in between the words. A mental map would have got created for jumping from one Quad Key to another Quad Key. Subsequent practice would automatically allow typing without having to see the legends.

### BRIEF DESCRIPTION OF THE DRAWINGS

FIG. 1 shows the diagram of the alphanumeric keypad

FIG. 2 shows ASCII Layout on alphanumeric keypad as per the present invention.

FIG. 3 shows the diagram of navigation keypad as per the present invention.

FIG. 4 includes 4a, 4b and 4c representing the profiles of the device.

FIG. 4a shows the side view of the device.

FIG. 4b shows the bottom view of the device.

FIG. 4c shows the top view of the device.

FIG. 5 shows the electronic circuitry of the device as per the present invention.

### DETAILED DESCRIPTION OF THE PREFERRED EMBODIMENTS

The description below is given along with drawings, in order to clarify the working of the device. The description pertaining to the electronics is peripheral to the invention and given for the sake of completeness and better understanding of typical application of the device.

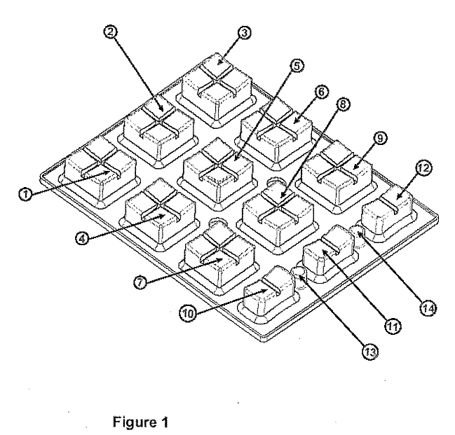

FIG. 1 shows the physical layout of the Alphabet Pad, with twelve keys from quad key blocks 1 to 12. It also gives the dimensions of the keypad and the main Key blocks.

Key blocks 1 to 9 are the quad keys that function individually as a four-way rocker switches. Generous gaps are given between the quad key blocks, as required to prevent accidental pressing of the adjoining keys while minimizing the thumb movement. Each quad key can be tipped by pressing on any of the four corners, whereby the electric contact below that corner is activated. The dashed lines within a quad key show the separation into four keys, each of which can be used for typing a separate character. The quad keys have concave surface, such that the raised corners are easily felt by a thumb. These kinds of rocker switches are quite popular for direction based actuation in consumer devices—the primary difference is the diagonal orientation. Alternatively these quad keys can be implemented using four separate switches. In this case a common key cap can cover the four switches and make them appear as a single key block.

Keys 10 to 12 are recessed two-way dual switches. Their height is such that when the keys are pressed they are at the level of the top surface of the device. In contrast quad keys 1 to 9 are raised above such that when they are pressed, they are still above the heights of the recessed keys, which otherwise may get pressed.

Quad key 5 is the homing key and is placed in the centre and serves as a convenient reference point. Quad keys 1-4 and 5-9 are placed around the homing key such that it is possible for a thumb to stroke them without pressing the adjoining keys.

Key blocks 10, 11 and 12 are dual keys or two-way rocker switches, as commonly found in the volume control buttons on consumer remote controls. The dashed line in each Key block demarcates the two keys. The electric contacts are located below the left and right edges of a Key block. The dual keys 10, 11 and 12 have sufficient space below them, so that a thumb can stroke them without colliding with the raised key blocks just above them. Alternatively, each of these key blocks could have been implemented with separate key switches.

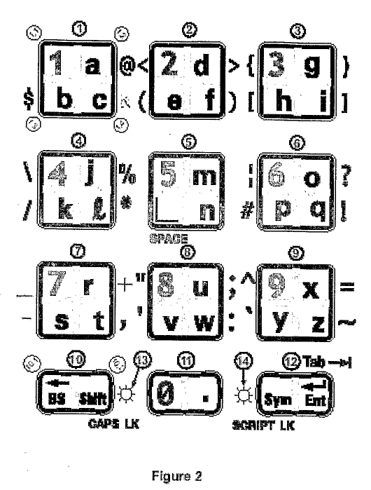

FIG. 2 shows the layout of an alphanumeric keypad according to the present invention. The top left corner of each quad key contains the numbers 0-9 and 26 lower-case letters of the English alphabet are accommodated on the remaining three corners of the key blocks 1 to 9, such that each letter is on a separate key. For “User Obviousness” purpose they are laid out in the alphabetic sequence, in a normal reading order (raster scan), so that locating and learning is not a problem.

The Space character is allotted to the Homing key 5, since that will ensure that homing of the thumb will occur after each word.

A Short press of a key in the alphanumeric keypad will output the lower-case letter as shown on the key legend. A long press of the same key will output the upper-case letter. This provides an intuitive, and efficient way of deriving the upper case letter without having to press a shift key, as in conventional keyboards.

When a long sequence of upper case letters have to be typed, it is better to select the Caps overlay by Long press of the Caps lock key (not shown). With this the Caps lock LED (13) will light up. On a subsequent press of the Caps lock key, the Caps lock LED will go off. The Caps overlay is case-wise opposite of the Alpha overlay: Short press for upper case and Long press for the lower case.

Apart from the letters and numbers each quad key can output punctuations as shown in the key legends. But, for this the Punctuation overlay has to be selected. The punctuation overlay also extends over the Key blocks 1 to 9.

When the punctuation overlay is active, then a short press of a key would output the second character on the key legend. A long press would output the third character on the key legend, if present.

Punctuation overlay is activated with a Long press of Shift key. (10.2). Subsequent Long press of the Shift lock key would re-activate the Caps overlay.

At any time, it is possible to temporarily shift from the current overlay, for typing a single key from the other overlay.

Key 10.1 allows BS (Back Space) to be typed for erasing the previous character. This key has an auto-repeat feature; so multiple BS characters are output as long it is pressed.

Key 11 accommodates the number ‘0’ and the dot (.) character. Key 12 outputs an Enter character as well as the ‘Symbol’ function. A long press on key 12 outputs a ‘Tab’ character.

Sym key (12) is used for deriving letters and symbols not directly shown on the ASCII layout, and which is part of the Extended ASCII character set. When Sym key is typed, the Caps lock LED (13) located below it starts blinking and a two character mnemonic (based on the key legends) is typed. The Extended ASCII character corresponding to the mnemonic is then output, and the Caps lock LED stops blinking. For example a “u” with an “umlaut” will be indicated by typing “:” followed by typing of “u”. If a capital “U” with an umlaut is needed, then in the previous example the second character ought to be “U” (A Long Press). In the example above the key containing colon is typed, and not the colon character. Please note that only a Short press of the key containing the legend for the first character after Sym is required. In this manner Sym key (12) allows output of all the additional characters required for European languages as contained in the Extended ASCII character set.

The Sym key followed by Space key (5) and then the “e” (key 2), will output the Euro symbol. In general Sym followed by Space key, will allow output of various symbols on the subsequent key. In this manner the Sym key allows output of all the Extended ASCII Symbols such as ®, Degree, Euro and Copyright.

The Alpha and the Caps overlays in conjunction with the Sym key, permit typing of most of the languages written in the Latin script (Roman script) with characters in the Extended ASCII character set, or in the first two code pages (256 characters) of the UNICODE.

The device permits typing of most of the non-Latin script languages too using Script overlays. Most of the Script overlays can use a scheme where by the Latin transliteration (also called Roman transliteration) is actually typed using the existing English legends on the keys. Additional unique characters in the script can be typed using the Sym key. In this manner, it is possible to type in non-Latin phonetic/alphabetic scripts such as Indian scripts, Perso-Arabic scripts, Cyrillic, Thai, Tibetan, Bhutanese, Burmese and Sinhalese,

The required non-Latin script can be pre-configured in the device or selected from a menu on Local or External display. The Script lock key will now allow toggling between the ASCII overlays and the Script overlays.

If the selected script is case sensitive, such as Cyrillic, then the Caps lock will select between the applicable lower-case and upper case overlay of the Cyrillic script. The Sym key, followed by one or two characters, would now be used to select characters, which are not directly available on the alphabet keys. Note that the Caps lock LED (13) will blink for one or two characters as needed for the script. If the selected script doesn't have two cases, such as the Indian scripts, then the Caps lock normally won't have any effect on the Script overlay (unless the Caps lock is made to select another special purpose overlay for the script). In Indian scripts the Sym key can be followed by one of the script overlay characters to derive a related script character. Some other non-Latin scripts may require two characters following the Sym key.

The ASCII Symbols are also typed in the same way, while using the Script overlay, by following Sym key with Space key and another character key. The Caps lock LED, will in this case blink for two characters.

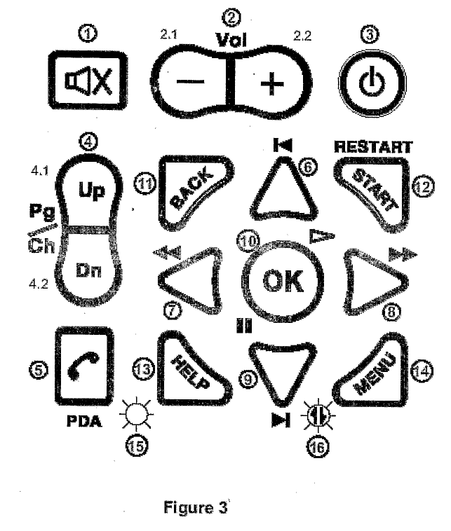

FIG. 3 shows the layout of the navigation keypad that is located above the Alphabet keypad on the top surface of the device. The navigation keypad complements the alphanumeric keypad to provide equivalent functionality of conventional PC keyboards.

The MUTE/HIDE key (1), volume control key (2) and power on/off key (3) are placed on the top row. Key 2.1 increases the volume while key 2.2 decreases the volume; both work on an auto-repeat basis.

A Short press on MUTE/HIDE key will causes the sound to be muted or un-muted on a toggle basis. Mute will be deactivated when either of the volume keys 2.1 or 2.2 is pressed. A Long press will work, as a HIDE key toggle It will cause a text overlay on a video/image on an External display to be hidden or revealed.

Keys 6,7,8 & 9 are the four direction keys, which on a Long press would auto-repeat.

Key 10 is the OK key, which causes an item to be selected on the Local display or an External display (of a PC or a TV). Key 10 also works as a left-mouse key in conjunction with the pointing device. A Long press of the OK can be used for selecting a related action.

BACK key (11), will cause quitting to a previous screen of an application. HOME key (Long press on key 10) would show the Home screen on the local or External display. The result of the HOME key is the same as that of a series of BACK keys: thus the positioning as Long press.

START key (Short press on key 12), is used typically to show the Start screen/menu on the External display. STANDBY key (Long press on key 12), can put the External display device in the Standby mode, or wake it up if it was in the Standby mode.

MENU key (Short press on key 14) will cause a context sensitive menu to pop up on the Local or External display, much like the right-mouse click menu on a Windows screen.

LOCAL MENU key (Long press on key 14) allows a Local menu to be displayed on the Local display of the device. The Local menu allows local settings of device modes and configurations,

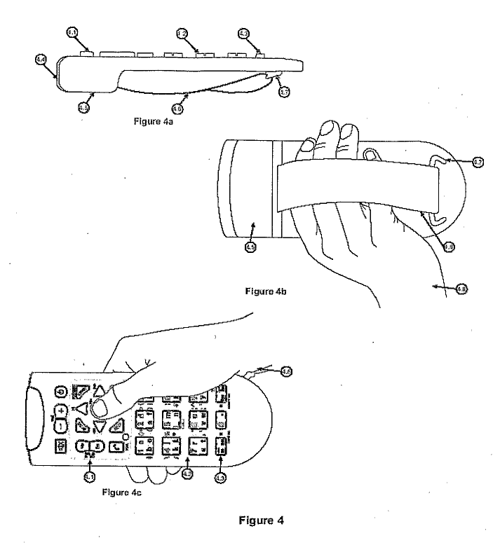

FIG. 4 shows representative views of a preferred embodiment of the device, with the pointing device as a track-ball. Although the right-hand examples are given out here, the device could have very well have been held and operated by the left-hand.

FIG. 4a shows a side-view of the device. FIG. 4b shows a bottom view of the device, with right-hand positioned to use the device. FIG. 4c shows a top view of the device, with right-hand positioned to use the device. The thumb is over the Homing key.

The top surface is nearly flat and contains the Navigation keypad (4.1), Alphabet keypad (4.2) and Local display (4.3). The specific order is to facilitate thumb touch-typing by a hand (4.8). The central area with the Alphabet keypad (4.2) is the most convenient to stroke and has the Homing key. The Navigation keypad (4.1) is accessible by flexing the thumb upwards. The Local display (4.3—mostly LCD display), in this embodiment, is located in the area, which is difficult for the thumb to reach.

The bottom surface of the device (4.6) has a slant, which tilts the palm such that the index finger is higher than the little finger. This tilt of the palm helps in making the thumb as parallel as possible to the top surface of the device—contributing to ease in thumb typing.

A Hand strap (4.7) is provided to keep the fingers of the hand (4.8) in proper place. The diagrams show four fingers inserted inside the strap, while the index finger can be also be made free to operate a pointing device—in this case a track-ball (4.5). If the pointing device (4.5) was not to be used, all the four fingers could have been inserted inside the Hand strap (4.7). As seen from the diagram, the fingers don't jut out of the device, so that the palm of the hand can be curved around a side of the device with the thumb getting raised high-enough for proper access of the keys. The Hand strap is placed in such a manner that it does not come in the way of proper horizontal placement of the device on a desktop, for sight typing with fingers.

The track ball (4.5) is positioned such that the index finger can slide over it, and in the process moves the track ball in the desired direction. For moving a pointer vertically upwards on a screen, the index finger starts from the strap adjacent position, gets pushed away from the device as it slides to the centre of the track ball and gets splayed towards the top edge (4.4) of the device. For horizontal movement of a pointer on a screen, the index finger moves inwards or outwards from the palm.

The OK and Menu Key in the Navigation keypad (4.1) are stroked by the thumb, for getting equivalent of left-click and right-click on a conventional mouse device. The thumb can act in parallel with index finger, which may be moving the track-ball.

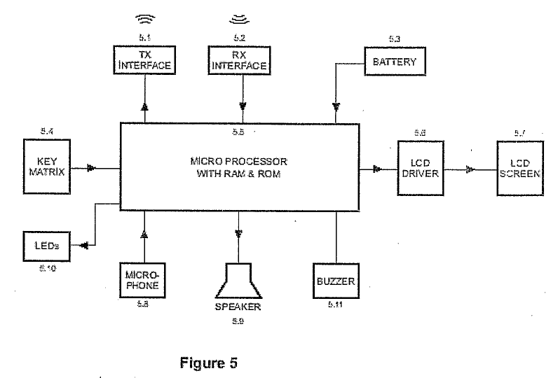

FIG. 5 shows the electronic circuitry of the device. The microprocessor (5.5) and entire electronics is powered by a battery (5.3). Power conservation is exercised by putting the microprocessor in the sleep mode, whenever possible, and waking it through an event such as key press, wake-up timer or received character. The microprocessor and many of the peripherals can be incorporated in a single ASIC, for purpose of clarity many of the peripherals are shown separately. The microprocessor can contain enough RAM, ROM, and E2PROM/FLASH memory as required.

The Microprocessor scans the key matrix (5.4), which allows detection of any key pressed. Software logic ensures that a key contact is recognized only when no other key is pressed simultaneously within the same Key block.

Microprocessor sends and receives characters via TX interface (5.1) and RX interface (5.2) respectively. These interfaces can allow communication via infrared or RF. Alternatively the TX and RX interfaces can be for a wired protocol such as USB.

The Microprocessor drives the LCD screen (5.7) through a LCD Driver (5.6). It can also display some status signals through LEDs (5.10).

The Microprocessor takes in the signals from a pointer device 5.10 (such as a track ball). The mouse buttons for this device are detected through the key matrix (5.4).

The Microprocessor can also take in a microphone input (5.8) through an internal A/D converter, and output an analog signal for driving a speaker (5.9). It can also drive a Buzzer (5.11)

While particular embodiments of the invention have been shown and described, it will be obvious to those skilled in the art that changes and modifications may be made without departing from the invention in its broader aspects. Therefore, the aim in the appended claims is to cover all such changes and modifications as fall within the true spirit and scope of the invention.

### APPENDIX

### European Language Symbols Through SYM Key

The Remote allows entry of all the accent marks and special symbols required for entry of European Languages: Spanish, French, Italian, Portuguese, Romanian, Norway, Sweden, Denmark, Holland, Germany, Austrian and even Turkish. Since North and South America also uses some of these languages, this takes care of the requirement of these two continents too.

In addition the SYM key allows typing of many special characters.

When the SYM key is pressed it starts blinking indicating the Symbol mode. When the next key is pressed the SYM key continues blinking, indicating that another key is needed. The key pressed next is output by the Remote, after which the SYM key light goes off.

A lighted SYM key can be turned off by pressing the SYM key again.

| | USAGE | WINDOWS | REMOTE |
|---|---|---|---|
| NAME | | | |
| Grave | ÀÈÌÒÙàèìòù | Ctrl + \grave{ } | SYM \grave{ } |
| Acute | [symbol] | Ctrl + ′ | SYM ′ |
| | [symbol] | | SYM - |
| Circumflex | ÂÊÎÔÛâêîôû | Ctrl + \hat{ } | SYM \hat{ } |
| Tilde | ÃÑÕãñõ | Ctrl + ~ | SYM ~ |
| Umlaut | ÄËÏÖÜŸäëïöüÿ | Ctrl + : | SYM : |
| Macron | [symbol] | Ctrl + @ | SYM @ a |
| | [symbol] | | |
| Cedilla | [symbol] | Ctrl + , | SYM , c |
| | Øø | Ctrl + / | SYM \| o |
| Ligatures | [symbol] | Ctrl + & (A S O) | |
| | [symbol] | | SYM s s |
| | [symbol] | | SYM a e |
| | [symbol] | | SYM o e |
| Hachek | \check{S}\check{s} \check{Z}\check{z} | Alt + Ctrl + \hat{ } | SYM v s |
| | | | SYM v z |
| | [symbol] | Alt + 0222, Alt + | SYM p P, |
| | | 254 | SYM p p |
| DIRECT | | | |
| Inverse Question | [symbol] | Alt + Ctrl + ? | SYM SP ? |
| Multiply | × | Alt 0125 | SYM SP x |
| Divide | ÷ | Alt + 0247 | SYM SP _{—} |
| Degree | ° | Ctrl + @ (Space) | SYM SP @ |
| Cent | ¢ | Ctrl + / | SYM SP / |
| Pound | £ | Alt + 0163 | SYM SP l |
| Yen | ¥ | Alt + 0165 | SYM SP y |
| Euro | [symbol] | Alt + Ctrl + E | SYM SP e |
| Copyright | © | Alt + Ctrl + C | SYM SP c |
| Registered | ® | Alt + Ctrl + R | SYM SP r |
| Trade Mark | ™ | Alt + Ctrl + T | SYM SP t |
| Bullet | • | Alt + 0149 | SYM SP . |
| Micro | μ | Alt + 0181 | SYM SP u |

The above sequences have been optimized for the Remote layout, so that the two keys following SYM can be typed conveniently, without much traversal.

The Single Symbols are generated with a SYM SP followed by a single key, which is graphically similar to the character being generated.

The characters generated by the Remote, is part of the Latin-1 character set and Latin Extended-A. This character set supports more characters as required for East European, Hungarian, and Cyrillic etc. languages. These characters are not supported directly on the CHOISer.

The SYM key allows selection of some of the Accent characters such as: Acute, Grave, Circumflex, Tilde, Umlaut, and Macron. These are selected by typing the SYM key before a key on the Alphanumeric pad which has a similar sign shown on it.

The Accent characters typed after the SYM key do not show up immediately on the display. They will get attached on a subsequent English alphabet typed afterwards.

The Remote allows direct output of some of the special characters through the SYM key. The SYM key works in a manner similar to that of the ALT key. For special characters one has to type SYM followed by SP key. For example: SYM and SP keys needs to be typed before ‘/’ to be able to get the Cent symbol. To get the Copyright symbol one just has to type a ‘c’ after the SYM and SP keys.

### Indian Languages Through SYM Key.

The Remote allows direct typing of all Indian language characters by mapping them to the closest characters in the English alphabet. A person types in Indian language words, in a manner similar to spelling them out using English characters. This takes away the need to depict the characters in the Indian scripts (which would be quite difficult on a Remote). While providing the convenience of typing a more complex character-set using the simple English alphabet, the Remote still ensures that a user gets a proper, stroke-by-stroke Indian script feedback on the screen, which would eliminate all the typing errors.

The basic methodology lies in distinguishing the short and long vowel, by short and long key presses of the corresponding English vowel. The soft and hard consonants, are distinguished by short and long key presses.

The SYM key is pressed before a Consonant, to derive its aspirated form:

Example SYM k, becomes kh on the screen. The SYM key is also used to obtain the alternate form of a vowel. Example: SYM e gives ‘ai’. Please note that in normal English spelling the same forms would have been typed as two characters (k, h, or a, i). However, in the latter-case it would not be possible to give a proper stroke-by-stroke feedback on the screen.

The Remote takes care of the special requirements of all the Indian languages, by providing the extra characters needed for them. The Remote can in an analogous manner, also cater to the other Brahmi-originating scripts: Tibetan (Bhutanese), and Sinhalese.
The SYM character is shown as in the tables below.
The long press is shown as capital letter.
As each consonant is treated as a pure consonant, an “a” needs to be typed after it.
Ending “a” is required, otherwise the ending will be shown with halant. (Except for northern scripts where halant at the end will not be shown).
The nomenclature is suitable for uniquely identifying each word in Roman transliteration.

Indian Script Vowels

| | | | | | | | |
|---|---|---|---|---|---|---|---|
| a | A | i | I | u | U | ′r | |
| ′e | e | E | ′E | ′o | o | O | ′O |

For the |r vowel, no extra vowel (i or u) needs to be added
(although they would get ignored).

Basic Consonants

| | | | | |
|---|---|---|---|---|
| k | kh | g | gh | ′m |
| c | ch | j | jh | ′M |
| t | th | d | dh | n |
| T | Th | D | Dh | ′n |
| p | ph | b | bh | m |
| y | r | l | L | v |
| s | sh | Sh | h | |

Nukta Consonants

| | | | | | | |
|---|---|---|---|---|---|---|
| q (′k) | ′kh(qh) | ′g | z (′j) | ′d | ′dh | f (′ph) |

Other Consonants

| | | | |
|---|---|---|---|
| ′n | Y | R | Z |

Visargh:

H

Anunasik

N

Anuswar

Is always converted before appropriate Vargs:
m, n, ′n
“n” is converted to Anuswar before the 1st
and 2nd Varg consonants.
(Thus people need not know how to type in the
corresponding nasal)

Conjunct

x (ksh)
′gy (as in gyaan)

1. A hand held thumb touch typable ASCII/UNICODE keyboard comprising:
an alphanumeric keypad having multiple quad keys and multiple dual keys;
a navigation keypad having multiple dual keys and single-function keys;
wherein each corner of one of said quad keys or dual keys of the alphanumeric keypad allow a user to type a separate character; and wherein a quad key at a center of the alphanumeric keypad is a homing key.

2. The hand held thumb touch typable ASCII/UNICODE keyboard as claimed in claim 1, wherein the alphanumeric keypad includes nine quad keys arranged in a rectangular array and three dual keys slightly recessed below the quad keys.

3. The hand held thumb touch typable ASCII/UNICODE keyboard as claimed in claim 1, wherein:
the multiple dual keys of the navigation keypad comprises one “UP/DOWN” key for volume and one “UP/DOWN” key for browsing one of a channel or a page; and
the single-function keys include four direction arrow-keys with a central “OK” key, four keys in a diagonal direction from the “OK” key, one ON/OFF key, one PDA key, and one MUTE key.

4. The hand held thumb touch typable ASCII/UNICODE keyboard as claimed in claim 1, wherein a short press of a said key and a long press of the same said key of said alphanumeric keypad outputs of different characters.

5. The hand held thumb touch typable ASCII/UNICODE keyboard as claimed in claim 1, wherein Arabic numbers are located on the top-left hand corners of the respective quad keys of said alphanumeric keypad.

6. The hand held thumb touch typable ASCII/UNICODE keyboard as claimed in claim 1, wherein the homing quad key further comprises:
the digit ‘5’ in the top-left corner;
a ‘SPACE’ character, below the digit ‘5’,
wherein the surface of the SPACE character is raised.

7. The hand held thumb touch typable ASCII/UNICODE keyboard as claimed in claim 5, wherein the letters of the English Alphabet are consecutively accommodated in remaining corners of the quad keys.

8. The hand held thumb touch typable ASCII/UNICODE keyboard as claimed in claim 7 wherein a first press of the English alphabet key outputs a lower-case letter, while a second longer press of the same key outputs an upper-case of the letter.

9. The hand held thumb touch typable ASCII/UNICODE keyboard as claimed in claim 2, wherein a middle dual key on the alphanumeric keypad contains the digit ‘0’ and the “DOT” character.

10. The hand held thumb touch typable ASCII/UNICODE keyboard as claimed in claim 2, wherein the left dual key on the alphanumeric keypad accommodates BACKSPACE and SHIFT functions, and the right dual key on accommodates the SYMBOL and ENTER/TAB functions.

11. The hand held thumb touch typable ASCII/UNICODE keyboard as claimed in claim 10 wherein the SHIFT key followed by another key outputs a punctuation character.

12. The hand held thumb touch typable ASCII/UNICODE keyboard as claimed in claim 10 wherein pressing said SYMBOL key followed by at least another key outputs a related Extended ASCII or UNICODE character.

13. The hand held thumb touch typable ASCII/UNICODE keyboard as claimed in claim 10 wherein a pressing the SHIFT key for a predetermined duration one of sets and resets the CAPS Lock LED indicator and changes the default case of the English alphabet.

14. The hand held thumb touch typable ASCII/UNICODE keyboard as claimed in claim 10 wherein a pressing the SYMBOL key for a predetermined duration one of sets and resets the SCRIPT Lock LED indicator and shifts between a “Script” overlay, or and a default English alphabet overlay.

15. The hand held thumb touch typable ASCII/UNICODE keyboard as claimed in claim 14, wherein the Script overlay allows a non-Roman script, to be typed.

16. The hand held thumb touch typable ASCII/UNICODE keyboard as claimed in claim 1, wherein, where thumb touch-typing is enabled on the navigation keypad.

17. The hand held thumb touch typable ASCII/UNICODE keyboard as claimed in claim 1, further comprising an adjustable hand-strap configured to accept one to four fingers of user's hand, wherein the palm of the user remains outside the strap.

18. The hand held thumb touch typable ASCII/UNICODE keyboard as claimed in claim 1, wherein all said keys are accessible by a thumb of a hand holding the keyboard.

19. The hand held thumb touch typable ASCII/UNICODE keyboard as claimed in claim 1, further comprising a pointing device.

20. The hand held thumb touch typable ASCII/UNICODE keyboard as claimed in claim 1, wherein an Arabic number is located on the left side of a respective said dual key of said alphanumeric keypad.

21. The hand held thumb touch typable ASCII/UNICODE keyboard as claimed in claim 12, wherein the related Extended ASCII or UNICODE character is at least one of a trademark symbol or an European character with a diacritic mark.

22. The hand held thumb touch typable ASCII/UNICODE keyboard as claimed in claim 15, wherein said non-Roman script is an Indian script.
